(19) United States
(12) Patent Application Publication
(10) Pub. No.: US 2023/0343760 A1
(43) Pub. Date: Oct. 26, 2023

(54) TRIMMABLE LED FILM

(71) Applicant: LightnTec GmbH, Karlsruhe (DE)

(72) Inventor: Martin Brueckel, Karlsruhe (DE)

(73) Assignee: LightnTec GmbH, Karlsruhe (DE)

(21) Appl. No.: 18/303,025

(22) Filed: Apr. 19, 2023

(30) Foreign Application Priority Data
Apr. 20, 2022 (DE) 10 2022 203 888.6

(51) Int. Cl. H01L 25/075; H01L 33/62; F21K 9/00

(52) U.S. Cl. CPC H01L 25/0753; H01L 33/62; F21K 9/00; F21Y 2105/14

(57) ABSTRACT

A method for producing an LED film with a cut-off edge is disclosed. The LED film has a film with LED pixels arranged thereon. The LED pixels, which each have at least one LED, are controlled via the data line of a daisy chain, which is arranged in a meandering shape on the film. The method provides for a loop of the meandering shape to be severed and for the thereby produced free ends of the data line to be connected or for a loop of the meandering shape to be bridged and for the edge of the LED film to be subsequently trimmed so that the loop is cut off outside the connection remaining on the LED film. Electrode paths of supply voltage lines are preferably arranged in a matrix shape on the LED film.

### CROSS-REFERENCE TO RELATED APPLICATIONS

This application claims priority to German Patent Application No. DE 10 2022 203 888.6 filed Apr. 20, 2022, the entire contents of which are hereby incorporated in full by this reference.

### DESCRIPTION

### Field of the Invention

The invention relates to a method for easy adaptation of an LED film.

### Background of the Invention

It is known to remove edge regions of electronic components in order to obtain a component adapted to the substrate. For example, electronic components with a multiplicity of LEDs have become known from EP 2 400 822 A2. The edges of the components can be removed, wherein the remaining LEDs can continue to be controlled.

### SUMMARY OF THE INVENTION

In contrast, the object of the invention is to provide a method for producing an LED film, which is structurally simplified and can be trimmed significantly more variably.

This object is achieved according to the invention by a method according to claim 1. The dependent claims reflect preferred embodiments.

The object according to the invention is thus achieved by a method for adapting the geometry of an LED film with the method steps of:
A) providing the LED film with:
   a) a bendable film;
   b) multiple LED pixels, arranged in a meandering shape in rows and columns on the film, with LEDs, wherein LED pixels are connected in a first daisy chain, wherein the first daisy chain has a first loop, the first leading row of which has multiple LED pixels and the first returning row of which has multiple LED pixels, wherein the end of the first leading row is connected to the beginning of the first returning row;
B1) cutting off a portion of the LED film, wherein both the first leading row and the first returning row are severed; and connecting the remaining new end of the first leading row to the remaining new beginning of the first returning rows; or
B2) connecting the first leading row to the first returning row and cutting off a portion of the LED film, wherein both the first leading row are severed after their connection points.

The structure of the LED film according to the invention allows trimming of the LED film for adaptation to differently shaped carriers. The connection in method steps B1 or B2 can relate to a data line and/or, preferably, to a supply voltage line.

In variant B1, a portion of the LED film is cut off before a corresponding connection takes place; in variant B2, a portion of the LED film is cut off after a connection has taken place, in particular with a pick and place machine, preferably with the same pick and place machine with which the LED pixels are applied to the film.

An LED pixel may have a control IC. The control IC may be connected to one or more LEDs. The LEDs may each have a respective control IC. The LED pixels may emit one or more light colors, in particular RGB, RGBW, W, warm white, cold white and/or amber per LED pixel.

The indications “row” and “column” should not be understood as “horizontal” and “vertical” but as an indication of an arrangement in a first direction and a second direction transverse, in particular perpendicular, to the first direction.

A film is understood here to mean an independent thin bendable sheet, in particular with a thickness of less than 5 mm, preferably of less than 3 mm, particularly preferably of less than 2 mm. The LED film can preferably be rolled in a non-destructive manner with an inner diameter of less than 1000 mm, in particular of less than 500 mm, particularly preferably of less than 300 mm.

The LED film can have multiple LED pixels connected by means of a second daisy chain.

In this case, the first daisy chain can be connected to a control line by means of a controllable first switch and the second daisy chain can be connected to the control line by means of a controllable second switch. This enables image construction, daisy chain by daisy chain, in a constructively particularly simple manner.

An LED film that can be trimmed particularly well is achieved if the second daisy chain is mirrored to the first daisy chain.

The connection in method step B1 or B2 can take place by means of a controllable switch, for example a MOSFET. However, in order to simplify the LED film, the connection preferably takes place by means of a shorting bridge or a mechanical switch.

The layout of the LED film is further simplified if the rows and columns of the matrix shape are at right angles to one another.

In a further preferred embodiment of the invention, the voltage supply of the LED pixels takes place by means of supply voltage lines applied in a matrix shape. In this case, supply voltage lines for applying a first pole, for example VCC, of a supply voltage for the LED pixels can be provided row-wise on a first layer or first side of the film. On the opposite, second layer or side of the film, supply voltage lines for conducting a second pole, for example GND, of the supply voltage can be provided column-wise. A via may be provided in each case in the region of the LED pixels. In this way, edge regions of the LED film can be removed very variably without endangering the voltage supply of the remaining LED pixels.

Edge regions of the LED film can be removed even more easily if a connection option for a cable line for the supply voltage and/or data line is present at multiple LED pixels. As a result, after the method step B1 or B2, at least one LED pixel can be supplied with voltage and/or data via the cable line.

Further advantages of the invention can be found in the description and the drawings. Likewise, according to the invention, the aforementioned features and those which are to be explained below can each be used individually or together in any desired combinations. The embodiments shown and described are not to be understood as an exhaustive list, but, rather, have an exemplary character for the description of the invention.

### BRIEF DESCRIPTION OF THE DRAWINGS

FIG. 1 shows an LED film with a bus control provisionally not according to the claims.

FIG. 2 shows an LED film according to the invention with multiple LED pixels in a daisy-chain control.

FIG. 3a shows a front portion of the LED film of FIG. 2, in which supply voltage lines for conducting a first pole of a supply voltage for the LED pixels can be seen.

FIG. 3b shows a rear portion of the LED film of FIG. 2, in which supply voltage lines for conducting a second pole of a supply voltage for the LED pixels can be seen.

FIG. 4 shows a further embodiment of an LED film which is provisionally not according to the claims and which has multiple LED pixels which can be controlled by various daisy chains.

### DETAILED DESCRIPTION OF THE PREFERRED EMBODIMENTS

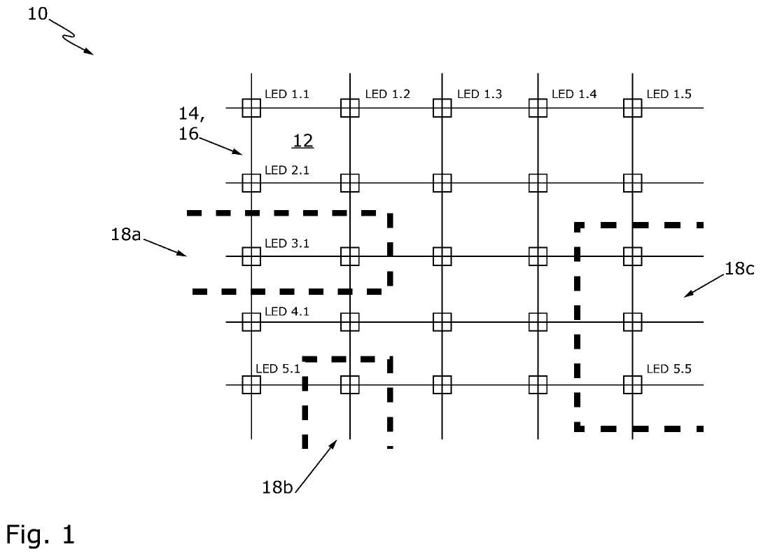

FIG. 1 shows an LED film 10 with a film 12 and multiple LED pixels LED n.m. The LED pixels LED n.m are connected both row-wise and column-wise via data lines 14 and supply voltage lines 16. The data lines 14 are designed as bus lines. The LED pixels LED n.m can be uniquely addressed individually. Edge regions 18a, 18b, 18c (contoured in dashed lines in FIG. 1) of the LED film 10 can be readily removed since all remaining LED pixels LED n.m, for example LED 5.1, can still be supplied via the remaining data and supply voltage lines 14, 16. The LED film 10 shown in FIG. 1 represents an independent part of the invention, which is provisionally not claimed herein.

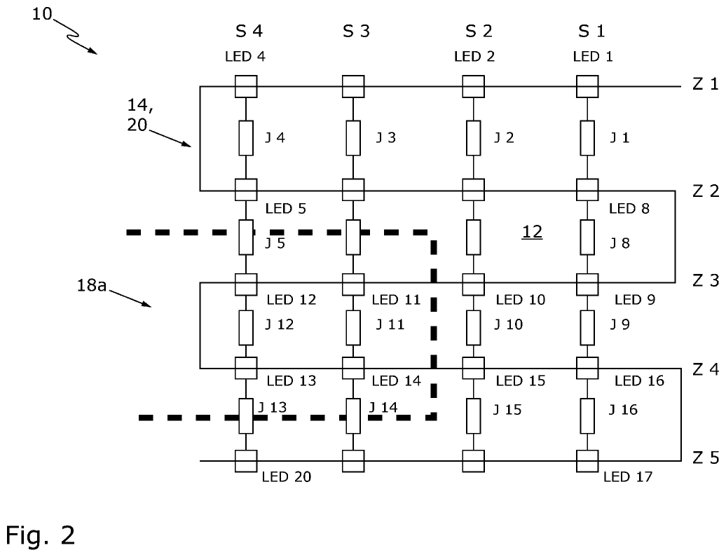

FIG. 2 shows an LED film 10 with a film 12 and multiple LED pixels LED n arranged thereon. The LED pixels LED n are connected in series via a data line 14 in the form of a daisy chain 20. The data line 14 is meander-shaped with rows Z 1 to Z 5 and columns S 1 to S 4. The rows Z 1, Z 3 and Z 5 are leading; the rows Z 2 and Z 4 are returning. Both the leading rows Z 1, Z 3 and Z 5 and the returning rows Z 2 and Z 4 are provided with LED pixels LED n.

The LED pixels LED n are or can be connected column-wise with jumpers J 1 to J 16 in order to repair the daisy chain 20 after removal of a portion of the LED film 10. In the present example, the edge region 18a (bordered by dashed lines) of the LED film 10 is removed. As a result, the LED pixels LED 15 to LED 20 can no longer be controlled. As a result of connecting the end of the leading row Z 3 to the beginning of the returning row Z 4, i.e., by setting or connecting the jumper J 10, the LED pixels LED 15 to LED 20 can be controlled.

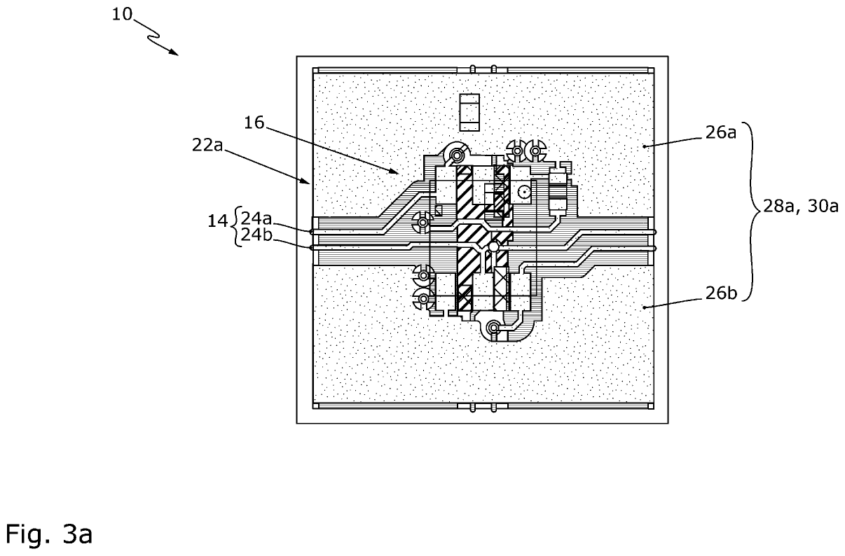

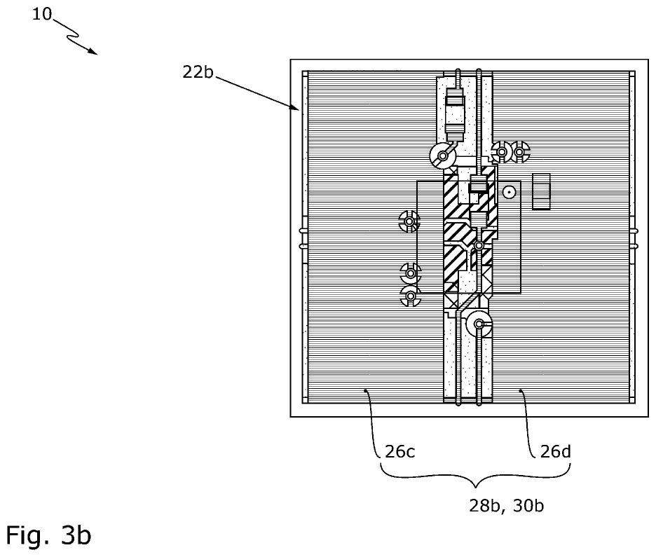

FIG. 3a shows a portion of a first layer 22a of the LED film 10 with the LED pixel LED 16. The data line 14, here with multiple electrode paths 24a, 24b, is arranged on the first layer 22a. Furthermore, row-wise guided electrode paths 26a,26b of a first supply voltage line 28a can be seen. The first supply voltage line 28a serves to supply the LED pixels LED n with a first pole 30a, here VCC.

FIG. 3b shows the rear side of the LED film 10 of FIG. 3a, i.e., a second layer 22b. In this second layer 22b, column-wise aligned electrode paths 26c,26d of a second supply voltage line 28b can be seen. The second supply voltage line 28b serves to supply the LED pixels LED n with a second pole 30b, here GND. The row-wise and column-wise voltage supply of the LED pixels LED n secures the voltage supply of the LED pixels LED n even in the case of large trimming of the edge region of the LED film 10.

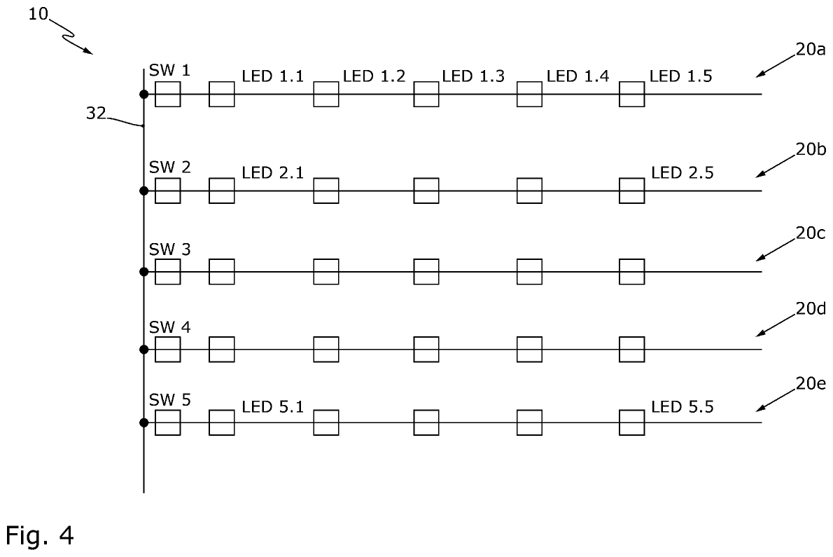

FIG. 4 shows a variant of an LED film 10 with multiple LED pixels LED n.m, which are arranged in daisy chains 20a, 20b, 20c, 20d, 20e. The daisy chains 20a-e are controlled via a common control line 32. The connection of the control line 32 to the daisy chains 20a-e takes place via controllable switches SW n, for example in the form of MOSFETs. In order to control the LED pixels LED n.m, only one switch SW n is ever switched on and the remaining switches SW n are switched off.

When combining all figures of the drawing, the invention thus relates in summary to a method for producing an LED film 10 with a cut-off edge 18a-c. The LED film 10 has a film 12 with LED pixels LED n.m, LED n arranged thereon. The LED pixels LED n.m, LED n, which each have at least one LED, are controlled via the data line 14 of a daisy chain 20, 20a-e, which is arranged in a meandering shape on the film 12. The method provides for a loop of the meandering shape to be severed and for the thereby produced free ends of the data line 14 to be connected or for a loop of the meandering shape to be bridged and for the edge 18a-c of the LED film 10 to be subsequently trimmed so that the loop is cut off outside the connection remaining on the LED film 10. Electrode paths (26a-d) of supply voltage lines (28a,b) are preferably arranged in a matrix shape on the LED film (10).

### LIST OF REFERENCE SIGNS

10 LED film
12 Film
14 Data line
16 Supply voltage line
18a-c Edge region of the LED film 10
20, 20a-e Daisy chain
22a,b Layer
24a,b Electrode path of data line 14
26a-d Electrode path of supply voltage line 28a,b
28a,b Supply voltage line
30a,b Pole
32 Control line
J n Jumper
LED n.m LED pixel
LED n LED pixel
S n Column
Z n Row
SW n Switch

What is claimed is:

1. A method for easy adaptation of an LED film comprises the steps of:
A) providing the LED film, wherein the LED film has the following:
a) a flexible film;
b) multiple LED pixels (LED n.m, LED n), which are arranged in a matrix shape in rows (Z n) and columns (S n) indirectly or directly on the film, wherein the LED pixels (LED n.m, LED n) are connected in a meandering shape in a first daisy chain, wherein the first daisy chain has a first loop, which has multiple LED pixels (LED n.m, LED n) in a first leading row (Z n) and has multiple LED pixels (LED n.m, LED n) in the following first returning row (Z n), wherein the first leading row (Z n) is connected at the end in the direction of a column (S n) to the beginning of the first returning row (Z n);
B1) cutting off a portion of the LED film, wherein the first leading row (Z n) and the first returning row (Z n) are severed; and connecting the end of the first leading row (Z n) to the beginning of the first returning row (Z n) before the cut-off portion;
or
B2) connecting the end of the first leading row (Z n) to the beginning of the first returning row (Z n) before a portion of the LED film to be cut off; and cutting off the portion of the LED film to be cut off, wherein the first leading row (Z n) and the first returning row (Z n) are severed.

2. The method according to claim 1, wherein the LED film has multiple LED pixels (LED n.m, LED n) connected in a second daisy chain.

3. The method according to claim 2, wherein the first daisy chain can be connected to a control line via a controllable first switch (SW n) and the second daisy chain can be connected to the control line via a controllable second switch (SW n).

4. The method according to claim 2, in which the second daisy chain is mirrored to the first daisy chain.

5. The method according to claim 3, in which the second daisy chain is mirrored to the first daisy chain.

6. The method according to claim 1, wherein the connection in method step B1 or B2 takes place by means of a shorting bridge (J n) or a switch.

7. The method according to claim 1, wherein rows (Z n) and columns (S n) of the matrix shape are at right angles to one another.

8. The method according to claim 1, wherein supply voltage lines for conducting a first pole of a supply voltage for the LED pixels (LED n.m, LED n) are arranged row-wise on a first layer of the film and supply voltage lines for conducting a second pole of the supply voltage for the LED pixels (LED n.m, LED n) are arranged column-wise on the opposite, second layer of the film, wherein in the region of the LED pixels (LED n.m, LED n), at least one via is provided in each case in order to supply the LED pixels (LED n.m, LED n) with voltage.

9. The method according to claim 1, wherein connection options for cable lines for the supply voltage and/or data line are present on multiple LED pixels (LED n.m, LED n).
